(19) United States
(12) Patent Application Publication
(10) Pub. No.: US 2012/0212717 A1
(43) Pub. Date: Aug. 23, 2012

(54) EXPOSURE APPARATUS AND PHOTO MASK

(75) Inventor: Makoto HATANAKA, Yokohama-shi (JP)

(73) Assignee: V TECHNOLOGY CO., LTD., KANAGAWA (JP)

(21) Appl. No.: 13/454,605

(22) Filed: Apr. 24, 2012

Related U.S. Application Data
(63) Continuation of application No. PCT/JP2009/068604, filed on Oct. 29, 2009.

(51) Int. Cl. G03B 27/42; G03F 1/00

(52) U.S. Cl. 355/53; 430/5

(57) ABSTRACT

The present invention provides an exposure apparatus in which a photo mask having a plurality of openings, each having a predetermined shape, formed in a light shielding film mounted on one surface of a transparent substrate 9 is disposed proximately and oppositely to a subject 6 to be exposed, and patterns corresponding to the openings are formed by exposure on the subject to be exposed by irradiating the photo mask with a light beam L1 from a light source, in which a plurality of micro lenses for forming images of the openings on the subject to be exposed are disposed on the side of the subject to be exposed in such a manner as to correspond to the openings of the photo mask.

This application is a continuation of PCT/JP2009/068604, filed on Oct. 29, 2009.

### BACKGROUND OF THE INVENTION

1. Field of the Invention

The present invention relates to an exposure apparatus for exposing an image of a predetermined pattern with a photo mask disposed proximately and oppositely to a subject to be exposed and, in particular, to an exposure apparatus for enhancing a resolution of an exposure pattern so as to enable an image of a fine pattern to be exposed, and a photo mask.

2. Description of Related Art

In a conventional exposure apparatus, in particular, a conventional proximity exposure apparatus, a photo mask and a subject to be exposed are allowed to be disposed proximately to each other, and then, an image of a pattern formed on the photo mask is exposed onto the subject to be exposed. Such an exposure apparatus includes: a transparent glass plate provided with a close plane on the lower surface thereof, that can closely contact with the photo mask; mask adsorbing and holding device for adsorbing and holding the photo mask to and on the close plane; and glass plate holding device for holding the transparent glass plate in such a manner as to define a minute clearance between the photo mask and the member to be exposed (see, for example, Japanese Laid-Open Patent Application Publication No. 2005-300753).

However, in the above-described conventional exposure apparatus, the pattern formed on the photo mask is transferred as it is onto the subject to be exposed with an exposure light beam that transmits perpendicularly to the photo mask, and therefore, an image of the pattern on the subject to be exposed blurs caused by a visual angle (i.e., a collimation half angle) at a light source, thereby raising the problems of the degradation of a resolution, and thus, the prevention of the formation of a fine pattern by the exposure.

### SUMMARY OF THE INVENTION

Therefore, in view of the above-mentioned problems, it is an object of the present invention to provide an exposure apparatus that enables an image of a fine pattern to be exposed in an improved resolution of an exposure pattern, and a photo mask.

In order to achieve the above-mentioned object, an exposure apparatus according to the present invention has a configuration that a photo mask having a plurality of openings, each having a predetermined shape, formed in a light shielding film disposed on one surface of a transparent substrate is arranged proximately and oppositely to a subject to be exposed, and then, patterns corresponding to the openings are formed by exposure on the subject to be exposed by irradiating the photo mask with a light beam from a light source, a plurality of micro lenses for forming images of the openings on the subject to be exposed are disposed on the side of the subject to be exposed in such a manner as to correspond to the openings of the photo mask.

With the above-mentioned configuration, the photo mask having the plurality of openings, each having the predetermined shape, formed in the light shielding film disposed on one surface of the transparent substrate is arranged proximately and oppositely to the subject to be exposed; the plurality of micro lenses disposed on the side of the subject to be exposed in such a manner as to correspond to the openings, form the images of the openings on the member to be exposed; and the pattern corresponding to the opening is formed by exposure on the subject to be exposed with the irradiation of the light beam from the light source with respect to the photo mask.

Moreover, each of the micro lenses is formed on a surface opposite to a surface of the transparent substrate, on which the openings are formed. Thus, each of the micro lenses formed on the surface opposite to the surface of the transparent substrate, on which the openings are formed, forms the image of each of the openings on the subject to be exposed.

Additionally, each of the micro lenses is formed on one surface of another transparent substrate. Thus, each of the micro lenses formed on one surface of the other transparent substrate forms the image of each of the openings formed in the transparent substrate on the subject to be exposed.

In addition, the subject to be exposed is conveyed at a predetermined speed in parallel to one surface of the photo mask by conveying device, and the photo mask is intermittently irradiated with the light beam from the light source. Thus, the photo mask is intermittently irradiated with the light beam from the light source; each of the micro lenses forms the image of each of the openings of the photo mask on the subject to be exposed which is conveyed at the predetermined speed in parallel to one surface of the photo mask by the conveying device; and the patterns corresponding to the openings are sequentially formed by the exposure on the subject to be exposed.

Furthermore, a photo mask according to the present invention includes: a plurality of openings, each having a predetermined shape, formed in a light shielding film disposed on one surface of a transparent substrate; and a plurality of micro lenses disposed at the other surface of the transparent substrate in such a manner as to correspond to the openings, so as to form an image of each of the openings on a subject to be exposed disposed proximately and oppositely to the photo mask.

With the above-mentioned configuration, the image of each of the plurality of openings, each having the predetermined shape, formed in the light shielding film disposed on one surface of the transparent substrate is formed on the subject to be exposed disposed proximately and oppositely to the photo mask by the plurality of micro lenses disposed in such a manner as to correspond to the openings at the other surface of the transparent substrate.

According to a first aspect of the exposure apparatus, the plurality of micro lenses are disposed on the side of the subject to be exposed in such a manner as to correspond to the openings formed in the photo mask, and the micro lens form the images of the openings on the subject to be exposed. In this manner, the resolution of the exposure pattern can be enhanced. Therefore, a fine pattern having a line width of, for example, about 3 μm can be formed by proximity exposure. Hence, a pattern requiring a high resolution such as a transistor unit for a TFT substrate can be exposed and formed by using a proximity exposure apparatus which is inexpensive with a simple optical configuration, thereby reducing manufacturing cost of the TFT substrate.

According to a second aspect of the invention, the micro lenses are formed on the surface of the transparent substrate, opposite to the surface having the openings formed therein, thereby dispensing with any positional alignment between the openings and the micro lenses. Thus, the photo mask can be readily treated.

According to a third aspect of the invention, the photo mask having the plurality of openings formed therein is formed independently of the micro lenses, and therefore, when the photo mask is deficient or a deficiency occurs later, only the photo mask may be replaced with a new one. Thus, it is possible to suppress an increase in cost of the photo mask.

According to a fourth aspect of the invention, the plurality of subjects to be exposed can be sequentially conveyed while being exposed to the light beam, thereby increasing the number of subjects to be exposed per unit time. In the photo mask to be used in this case, at least the width of the subject to be exposed in the conveying direction may be smaller than that in an exposure region of the subjects to be exposed in the same direction, thereby reducing the size of the photo mask so as to reduce the manufacturing cost of the photo mask.

According to a fifth aspect of the photo mask, the plurality of openings are formed in the light shielding film disposed on one surface of the transparent substrate, and the plurality of micro lenses are disposed on the other surface in such a manner as to correspond to the openings, so that the micro lenses can form the images of the openings on the subject to be exposed which is disposed proximately and oppositely to the photo mask, thereby increasing the resolution of the exposure pattern. Therefore, a fine pattern having a line width of, for example, about 3 μm can be formed by proximity exposure. Hence, a pattern requiring a high resolution such as a transistor unit for a TFT substrate can be exposed and formed by using a proximity exposure apparatus which is inexpensive with a simple optical configuration, thereby reducing a manufacturing cost of the TFT substrate.

### BRIEF DESCRIPTION OF THE DRAWINGS

FIG. 1 is a front view showing the schematic configuration of an exposure apparatus in a preferred embodiment according to the present invention;

FIGS. 2A to 2C are views showing an example a photo mask according to the present invention, in which FIG. 2A is a plan view, FIG. 2B is a front view, and FIG. 2C is a bottom view;

FIG. 3 is an explanatory view showing image formation at an opening of the photo mask in a micro lens; and

FIG. 4 is an explanatory view showing a use example in which the opening and the micro lens are formed independently of each other.

### DESCRIPTION OF THE PREFERRED EMBODIMENTS

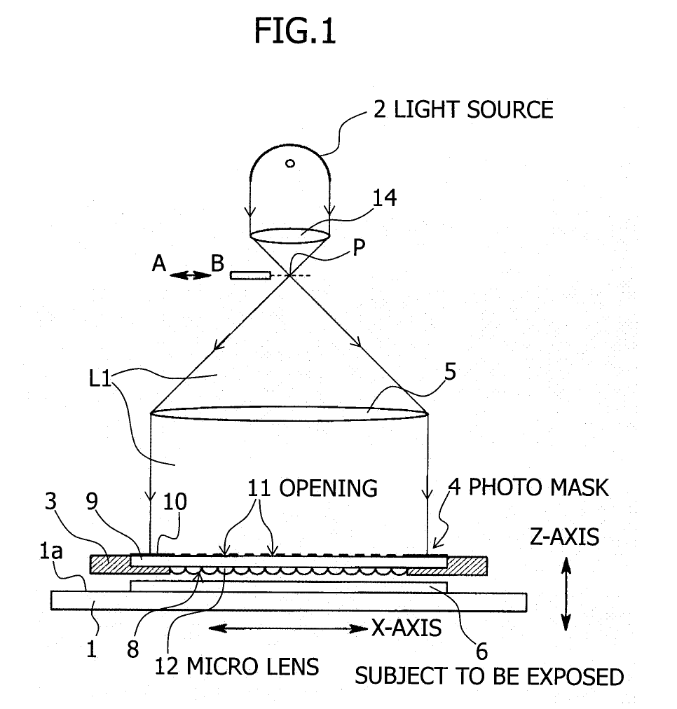

Hereunder an embodiment of the present invention will be explained in detail with reference to the accompanying drawings. FIG. 1 is a front view showing the schematic configuration of an exposure apparatus in an embodiment of the present invention. The exposure apparatus is adapted to expose a subject to be exposed to form a predetermined pattern on the subject to be exposed with a photo mask which is disposed proximately and oppositely to the subject to be exposed. The exposure apparatus includes a stage 1, a light source 2, a mask stage 3, a photo mask 4, and a collimation lens 5.

The stage 1 has a mount surface 1a obtained by forming a flat upper surface thereof, and then, positions a subject 6 to be exposed correctly on the mount surface 1a so as to, for example, adsorb and hold it. The stage 1 is designed to be freely moved within a plane parallel to the mount surface 1a in X-axial and Y-axial directions by a moving mechanism, not shown in the figure, and to be freely moved in a Z-axial direction, and furthermore, to be freely turned on a center axis perpendicular to the mount surface 1a. Here, the Y-axial direction indicates a depth direction in FIG. 1.

Above the stage 1 is disposed the light source 2. The light source 2 is adapted to irradiate the subject 6 to be exposed with a light beam L1 from the light source such as an ultraviolet ray, so as to expose a photosensitive resin applied onto the subject 6 to be exposed. The light source 2 is, for example, a xenon lamp, an extra high pressure mercury lamp, and an ultraviolet ray emitting laser for radiating an ultraviolet ray (having a wavelength of, e.g., 355 nm). Moreover, a condenser lens 14 is disposed, for example, forward in a radiation direction of the light beam L1 from the light source, so as to once collect the light beam L1 from the light source. At a focal point P, a shutter 7 that is moved in directions indicated by arrows A and B so as to shut an optical path traveling toward the subject 6 to be exposed from the light source 2, is located.

The mask stage 3 is interposed between the stage 1 and the light source 2 in such a manner as to face the stage 1. The mask stage 3 is adapted to hold the photo mask 4, described later, proximately and oppositely in parallel to the surface of the subject 6 to be exposed mounted on the stage 1. An opening window 8 is formed at the center in a manner corresponding to a pattern formation region of the photo mask 4. The mask stage 3 is designed to positionally restrict the photo mask 4 so as to hold it in the vicinity of the peripheral edge thereof.

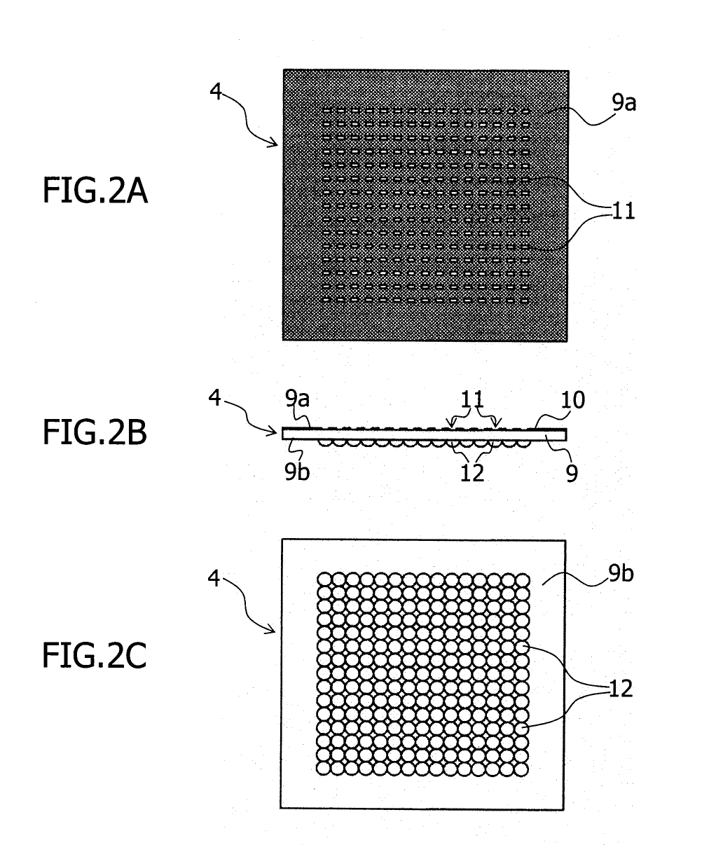

On the mask stage 3 is detachably held the photo mask 4. As shown in FIG. 2, the photo mask 4 has a plurality of openings (i.e., patterns) 11 formed into a predetermined shape at predetermined intervals in a matrix on a light shielding film 10 made of, for example, chromium (Cr) disposed at one surface 9a of a transparent substrate 9 made of, for example, quartz glass. A plurality of micro lenses 12, each of which, for example, has a magnification of ×0.25 and a focal distance of 0.683 mm with respect to the ultraviolet ray having a wavelength of 355 nm, are formed at a surface 9b of the transparent substrate 9 opposite to the surface 9a having the openings 11 in such a manner as to correspond to the openings 11, thereby forming an image of each of the openings 11 on the subject 6 to be exposed. In this case, the photo mask 4 is held on the mask stage 3 while the micro lenses 12 are oriented toward the subject 6 to be exposed, as shown in FIG. 1.

The collimation lens 5 is interposed between the mask stage 3 and the light source 2. The collimation lens 5 is adapted to collimate the light beams L1 radiated from the light source 2, and an anterior focal point coincides with the focal point P of the condenser lens 14.

Next, operation of the exposure apparatus such configured as described above, will be explained.

First, the light source 2 is turned on to be then lighted. At this time, the shutter 7 is closed. After a lapse of a predetermined period of time, when the light emission from the light source 2 is stabilized, the photo mask 4 is positionally mounted on the mask stage 3 in the state in which the micro lenses 12 face the stage 1, to be then adsorbed thereto and held thereon.

Next, the subject 6 to be exposed having the photosensitive resin applied thereonto is positionally mounted on the mount surface 1a of the stage 1, to be then adsorbed thereto and held thereon. Thereafter, an alignment mark previously formed at the photo mask 4 and an alignment mark previously formed at the subject 6 to be exposed are taken within the same field by imaging device, not shown in the figure, and then, the stage 1 is controlled to be moved in the X-axial and Y-axial directions by control device, not shown in the figure, so that the alignment marks is matched with each other. The stage 1 is turned at only a predetermined angle, as required, so that the photo mask 4 and the subject 6 to be exposed are aligned with each other. Upon the completion of the alignment between the photo mask 4 and the subject 6 to be exposed, the stage 1 is elevated by predetermined amount in the Z-axial direction such that a preset clearance is formed between the surface of the subject 6 to be exposed and the lower surface of the photo mask 4. Consequently, the micro lenses 12 corresponding to the openings 11 formed at the upper surface of the photo mask 4 form an image of the openings 11 on the subject 6 to be exposed.

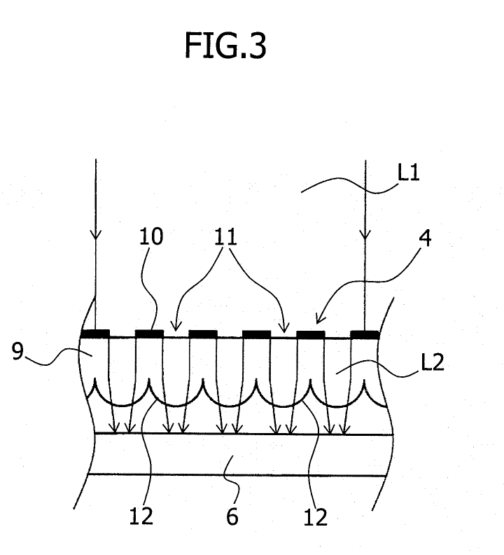

Subsequently, an exposure switch is turned on, and then, the shutter 7 is moved in the direction indicated by the arrow A to be opened only for a given period of time for exposure. In this manner, as illustrated in FIG. 3, the light beam L1 radiated from the light source 2 irradiates the photo mask 4, and then, an exposure light beam L2 passes through the opening 11 formed on the photo mask 4, to be focused on the subject 6 to be exposed by the micro lens 12. As a consequence, the micro lens 12 projects the image of the opening 11 onto the subject 6 to be exposed on a small scale, and furthermore, a pattern having a shape corresponding to the opening 11 is formed on the photosensitive resin applied thereonto by the exposure.

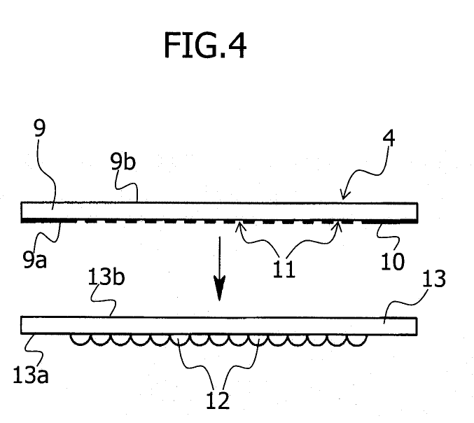

Although the description has been given of the use of the photo mask 4 having the openings 11 and the micro lenses 12 formed on one and the same transparent substrate 9 in the above-described preferred embodiment, the present invention is not limited to this. As illustrated in FIG. 4, the micro lenses 12 may be formed on another transparent substrate 13 independent of the photo mask 4 having the openings 11 formed therein. In this case, the photo mask 4 may be used such that the surface 9a having the openings 11 formed therein is brought into close contact with a surface 13b of the other transparent substrate 13 opposite to a surface 13a having the micro lenses 12 formed thereon, as indicated by an arrow in FIG. 4. Alternatively, when the micro lenses 12 can form the images of the openings 11 of the photo mask 4 on the subject 6 to be exposed, the surface 9b opposite to the surface 9a having the openings 11 formed therein, of the photo mask 4, may be brought into close contact with the surface 13b of the other transparent substrate 13 opposite to the surface 13a having the micro lenses 12 formed thereon.

Additionally, although the explanation has been made on the case in which the subject 6 to be exposed held at the predetermined position is exposed to the light beam, the present invention is not limited to this. The subject 6 to be exposed may be conveyed at a predetermined speed in parallel to one surface of the photo mask 4 by conveying device while the photo mask 4 is irradiated with the light beam L1 from the light source intermittently at preset time intervals, so that a pattern corresponding to the opening 11 of the photo mask 4 may be formed at a predetermined position of the subject 6 to be exposed by exposure. In this case, the irradiation of the light beam L1 from the light source may intermittently performed by using a flash lamp or moving the shutter 7. Furthermore, an imaging device is provided for capturing the subject 6 to be exposed at the exposure position by the photo mask 4 forward in a conveying direction, and then, the imaging device captures a reference position previously set at the subject 6 to be exposed, so that the photo mask 4 may be aligned with the subject 6 to be exposed based on the captured image. Here, the reference position or another reference position may be captured, and then, an irradiation timing of the light beam L1 from the light source may be controlled based on the captured image.

What is claimed is:

1. An exposure apparatus in which a photo mask having a plurality of openings, each having a predetermined shape, formed in a light shielding film mounted at one surface of a transparent substrate is disposed proximately and oppositely to a subject to be exposed, and patterns corresponding to the openings are formed by exposure on the subject to be exposed by irradiating the photo mask with a light beam from a light source,
wherein a plurality of micro lenses for forming images of the openings on the subject to be exposed are disposed on the side of the subject to be exposed in such a manner as to correspond to the openings of the photo mask.

2. The exposure apparatus according to claim 1, wherein each of the micro lenses is formed on a surface opposite to a surface of the transparent substrate on which the openings are formed.

3. The exposure apparatus according to claim 1, wherein each of the micro lenses is formed on one surface of another transparent substrate.

4. The exposure apparatus according to claims 1, wherein the subject to be exposed is conveyed at a predetermined speed in parallel to one surface of the photo mask by conveying device, and
the photo mask is intermittently irradiated with the light beam from the light source.

5. A photo mask comprising:
a plurality of openings, each having a predetermined shape, formed in a light shielding film disposed on one surface of a transparent substrate; and
a plurality of micro lenses disposed on the other surface of the transparent substrate in such a manner as to correspond to the openings, so as to form an image of the opening on a subject to be exposed disposed proximately and oppositely to the photo mask.
